(19) United States
(12) Patent Application Publication
(10) Pub. No.: US 2002/0050848 A1
(43) Pub. Date: May 2, 2002

(54) Voltage clamping circuit

(76) Inventors: Aleksandr Gitsevich, Montgomery Village, MD (US); Donald A. MacLennan, Gaithersburg, MD (US)

Correspondence Address: FUSION LIGHTING INC, PAUL E STEINER, 7524 STANDISH PLACE, ROCKVILLE, MD, 20855

(21) Appl. No.: 09/949,767

(22) Filed: Sep. 12, 2001

Related U.S. Application Data
(60) Provisional application No. 60/231,942, filed on Sep. 12, 2000.
(60) Provisional application No. 60/290,054, filed on May 11, 2001.

(51) Int. Cl. H03L 5/00

(52) U.S. Cl. 327/323

(57) ABSTRACT

A voltage clamping circuit includes a PIN diode with a first end connected to a signal line, a capacitor connected between ground and a second end of the PIN diode; and a reference voltage applied to a junction of the PIN diode and the capacitor. Dual arrangements of the clamping circuit may be used to limit a voltage on the signal line within a desired range. The voltage clamping circuit is effective for protecting RF power transistors from overdrive conditions while operating at frequencies above 300 MHz and power levels in excess of 50 watts. The voltage clamping circuit has minimal adverse impact on circuit operation and efficiency. Specific examples include a power oscillator providing over 170 RF watts at above 700 MHz with the voltage clamping circuit providing protection from destructive feedback.

### RELATED APPLICATIONS

This application claims priority to U.S. provisional application no. 60/231,942, filed Sep. 12, 2000, and U.S. provisional application no. 60/290,054, filed May 11, 2001, each of which is incorporated by reference herein in its entirety.

Certain inventions described herein were made with Government support under Contract No. NAS10-99037 awarded by National Aeronautics and Space Administration. The Government has certain rights in those inventions.

### BACKGROUND

1. Field of the Invention

The invention relates generally to voltage clamping circuits and more specifically to a voltage clamping circuit for protecting the input of a transistor used in an RF amplifier or oscillator.

2. Related Art

Zener diodes typically find application as voltage regulators placed in parallel with a load. The Zener diode is generally connected in between the drive signal and the load. Many voltage limiting circuits utilize Schottky diodes. A crowbar circuit is a surge protector circuit which may utilize thyristor devices.

Some commercially available RF transistors are pre-packaged with a voltage limiting diode. For example, a transistor with Motorola part no. MRF9060MR1 includes a buried Schottky diode with the cathode connected to the gate of the transistor and the anode connected to the source of the transistor. The diode is connected to the transistor inside the transistor package so that the package just has the conventional leads and connections for the gate, drain, and source of the transistor. The diode limits the amount of voltage that can develop on the gate during the negative cycle of a signal, but does not limit the positive cycle. It is believed that the integrated protection diode has a self bias behavior which increases the transistor current at the working point. Accordingly, the integrated protection diode significantly reduces the efficiency and power output of an amplifier and/or oscillator using this device as compared to a comparable device without the diode.

At RF frequencies, the PIN diode may be thought of as a voltage controlled resistor. According to The PIN Diode Circuit Designers' Handbook, published by Microsemi-Watertown (1999, Watertown, Mass.), when the forward bias control current of the PIN diode is varied continuously, the PIN diode finds application in attenuating, leveling, and amplitude modulation of an RF signal. When the control current is switched on and off, the PIN diode finds application in switching, pulse modulation, and phase shifting of an RF signal. Voltage clamping is not identified as a possible application for a PIN diode.

### SUMMARY

The following and other objects, aspects, advantages, and/or features of the invention described herein are achieved individually and in combination. The invention should not be construed as requiring two or more of such features unless expressly recited in a particular claim.

One aspect of the invention relates to improved protection of an active device from an out of range voltage condition on its input. Another aspect of the invention is improved protection of the active device of an oscillator from destructive feedback.

In contrast to what is suggested by the prior art, one aspect of the present invention is the utilization of a PIN diode in a voltage clamping circuit. Another aspect of the present invention which goes against conventional thinking is the utilization of a Zener diode on the input of an active device. The combination of the PIN diode and the Zener diode in a voltage clamping circuit overcomes problems with utilizing a Schottky diode at very high frequencies (e.g. above 300 MHz, 500 MHz, or more), particularly at higher power levels (e.g. above 50 or 100 watts).

According to one aspect of the invention, a voltage clamping circuit includes a first side limiter circuit connected to a signal line and adapted to inhibit a voltage on the signal line from going above an upper voltage limit, and a second side limiter circuit connected to the signal line and adapted to inhibit a voltage on the signal line from going below a lower voltage limit, wherein a signal on the signal line has a frequency above 300 MHz and a power level above 50 watts, and wherein each of the first and second side limiter circuits comprise a PIN diode connected to the signal line and adapted to conduct when the signal goes outside of the respective upper and lower voltage limits. Preferably, each of the PIN diodes provides a fast forward recovery time. For example, the frequency of the signal is greater than 400 MHz and each of the PIN diodes provides a forward recovery time sufficiently fast to start clamping the signal in less than 100 nanoseconds. Where the frequency of the signal is greater than 1 GHz, each of the PIN diodes provides a forward recovery time sufficiently fast to start clamping the signal in less than 1 nanosecond. For example, each of the first and second side limiter circuits further comprises a Zener diode connected at a first terminal to a bias voltage selected to set the respective voltage limit and at a second terminal to ground, the first terminal of the Zener diode is also connected to a first terminal of the PIN diode, a capacitor connected at a first terminal to the first terminal of the PIN diode and at a second terminal to ground, and the PIN diode is connected at a second terminal to the signal line.

According to another aspect of the invention, a voltage clamping circuit includes a PIN diode with a first end connected to a signal line, a capacitor connected between ground and a second end of the PIN diode, and a reference voltage applied to the junction of the PIN diode and the capacitor. For example, the circuit further includes a Zener diode with an anode end of the Zener diode connected to ground and the reference voltage is provided by a bias voltage connected to the cathode end of the Zener diode and a cathode end of the PIN diode is connected to the cathode end of the Zener diode. Alternatively, the circuit further includes a Zener diode with a cathode end of the Zener diode connected to ground and the reference voltage is provided by a bias voltage connected to an anode end of the Zener diode and an anode end of the PIN diode is connected to the anode end of the Zener diode. The signal on the signal line may be an RF signal at a frequency of 300 MHz, 500 MHz, 700 MHz, or more. The power level of the RF signal may be 50 or 100 watts or more.

According to yet another aspect of the invention, a voltage clamping circuit includes a first and second PIN diode, a first and second Zener diode, and a first and second capacitor, wherein an anode end of the first PIN diode and an cathode end of the second PIN diode are connected to a signal line, the first capacitor is connected between the cathode end of the first PIN diode and ground, a cathode end of the first Zener diode is connected to the cathode end of the first PIN diode and an anode end of the first Zener diode is connected to ground, a first bias voltage is applied to the cathode end of the first Zener diode, and wherein the second capacitor is connected between the anode end of the second PIN diode and ground, an anode end of the second Zener diode is connected to the anode end of the second PIN diode and a cathode end of the second Zener diode is connected to ground, and a second bias voltage is applied to the anode end of the second Zener diode. The signal on the signal line may be an RF signal at a frequency of 300 MHz, 500 MHz, 700 MHz, or more. The power level of the RF signal may be 50 or 100 watts or more.

According to another aspect of the invention, an oscillator includes a solid state active device having an input and an output, a feedback circuit connected from the output of the active device to the input of the active device, the feedback circuit providing suitable positive feedback to initiate and sustain an oscillating condition at a fundamental frequency, and a voltage clamping circuit connected to the input of the active device. The voltage clamping circuit includes a PIN diode connected at a first terminal to the input of the active device, a capacitor connected between a second terminal of the PIN diode and ground, and a reference voltage applied to a junction of the PIN diode and the capacitor. In some examples, the oscillator further includes a second voltage clamping circuit to clamp a voltage on the input of the active device within a range of upper and lower voltage limits. The fundamental frequency of the oscillator is generally above 300 MHz and the output power level is generally above 50 watts.

According to another aspect of the invention, an RF amplifier includes a solid state active device having an input and an output, and a voltage clamping circuit connected to the input of the active device. The voltage clamping circuit includes a PIN diode connected at a first terminal to the input of the active device, a capacitor connected between a second terminal of the PIN diode and ground, and a reference voltage applied to a junction of the PIN diode and the capacitor. In some examples, the RF amplifier further includes a second voltage clamping circuit to clamp a voltage on the input of the active device within a range of upper and lower voltage limits. A signal on the input of the active device generally has a frequency of above 300 MHz and the output power level is generally above 50 watts.

According to another aspect of the invention, an multi-stage amplifier comprises two or more stages connected in series, each stage including an active device having an input and output, and a protection circuit connected to the input of one or more of the active devices, where the protection circuit comprises a voltage clamping circuit as described above. In some examples an earlier stage has a faster clamping time but a lower power handling capacity as compared to a later stage.

### BRIEF DESCRIPTION OF THE DRAWINGS

The foregoing and other objects, features, and advantages of the invention will be apparent from the following more particular description of preferred embodiments as illustrated in the accompanying drawings, in which reference characters generally refer to the same parts throughout the various views. The drawings are not necessarily to scale, the emphasis instead being placed upon illustrating the principles of the invention.

FIG. 1 is a block diagram of an amplifier utilizing a protection circuit according to the present invention.

FIG. 2 is a block diagram of a multi-stage amplifier utilizing a protection circuit according to the present invention.

FIG. 3 is a block diagram of a conventional RF oscillator system.

FIG. 4 is a block diagram of an RF system including a protection circuit in accordance with a present aspect of the invention.

FIG. 5 is a block diagram of a protection circuit according to the present invention.

FIG. 6 is a schematic diagram of an example of a protection circuit according to the present invention.

FIG. 7 is another schematic diagram of an example of a protection circuit according to the present invention.

FIG. 8 is a graph of operating characteristics for a PIN diode in the protection circuit of the present invention.

FIG. 9 is a graph of turn on characteristics for a PIN diode.

FIG. 10 is a first graph of representative operation of a protection circuit according to the present invention.

FIG. 11 is a second graph of representative operation of a protection circuit according to the present invention.

FIG. 12 is a schematic diagram of a third example of an oscillator according to the present invention, including a protection circuit.

FIG. 13 is a printed circuit board diagram for the third example.

FIG. 14 is an enlarged, fragmented assembly level diagram of the third example.

FIG. 15 is an assembly level diagram of a fourth example of an oscillator including the protection circuit.

FIG. 16 is a combined graph of power versus drain voltage and efficiency versus drain voltage for the fourth example.

FIG. 17 is a printed circuit board layout for a fifth example of an oscillator according to the present invention, including an optional directional coupler circuit.

FIG. 18 is an assembly level diagram of the fifth example.

FIG. 19 is a combined graph of power versus drain voltage and efficiency versus drain voltage for the fifth example.

FIG. 20 is a graph of frequency of operation versus control voltage for the fifth example.

### DESCRIPTION

In the following description, for purposes of explanation and not limitation, specific details are set forth such as particular structures, interfaces, techniques, etc. in order to provide a thorough understanding of the various aspects of the invention. However, it will be apparent to those skilled in the art having the benefit of the present disclosure that the various aspects of the invention may be practiced in other examples that depart from these specific details. In certain instances, descriptions of well known devices, circuits, and methods are omitted so as not to obscure the description of the present invention with unnecessary detail.

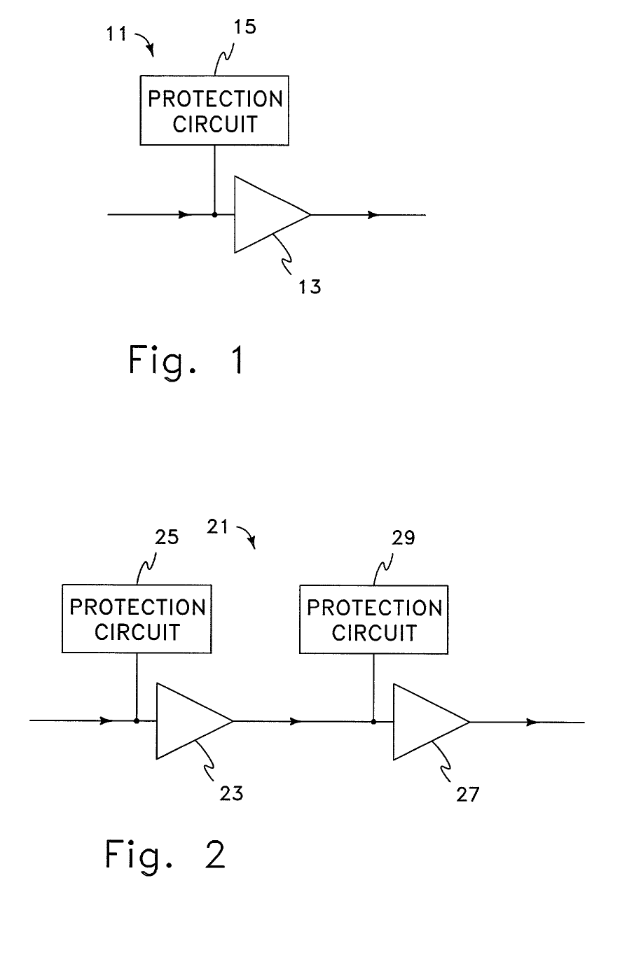

With reference to FIG. 1, an RF amplifier 11 includes an active device 13 which amplifies a high frequency signal on its input. A protection circuit 15 is connected to the input of the active device 13. The protection circuit 15 inhibits the signal on the input of the active device 13 from going outside of safe operating parameters for the active device 13. In other words, the protection circuit 15 protects the active device 13 from a destructive drive signal. For example, where the active device 13 is a uni-polar transistor, the protection circuit 15 protects the gate of the transistor. For example, the protection circuit 15 may comprise a voltage clamping circuit which clamps the minimum and maximum voltages that can appear at the gate within an acceptable range.

With reference to FIG. 2, a multi-stage RF amplifier 21 includes a plurality of stages 23 and 27 connected in series with associated protection circuits 25 and 29. Each stage includes an active device and the protection circuits 25 and 29 are respectively connected to the inputs of the active devices in the stages 23 and 27. In connection with an amplifier, the voltage protection circuit of the present invention may reduce the amount of isolation required between the final amplification stage and ground. Depending on the time scale and the nature of the overdrive signal, the clamping circuit may further be configured to handle a significant amount of excess energy. The amplifier 21 may utilize both faster and slower pin diodes in respective stages to provide both fast response and good power handling. For example, earlier stages may use low power, fast response diodes while later stages may use slower response, higher power diodes. The stages using the protection circuit are not necessarily consecutive and every stage does not necessarily require a protection circuit.

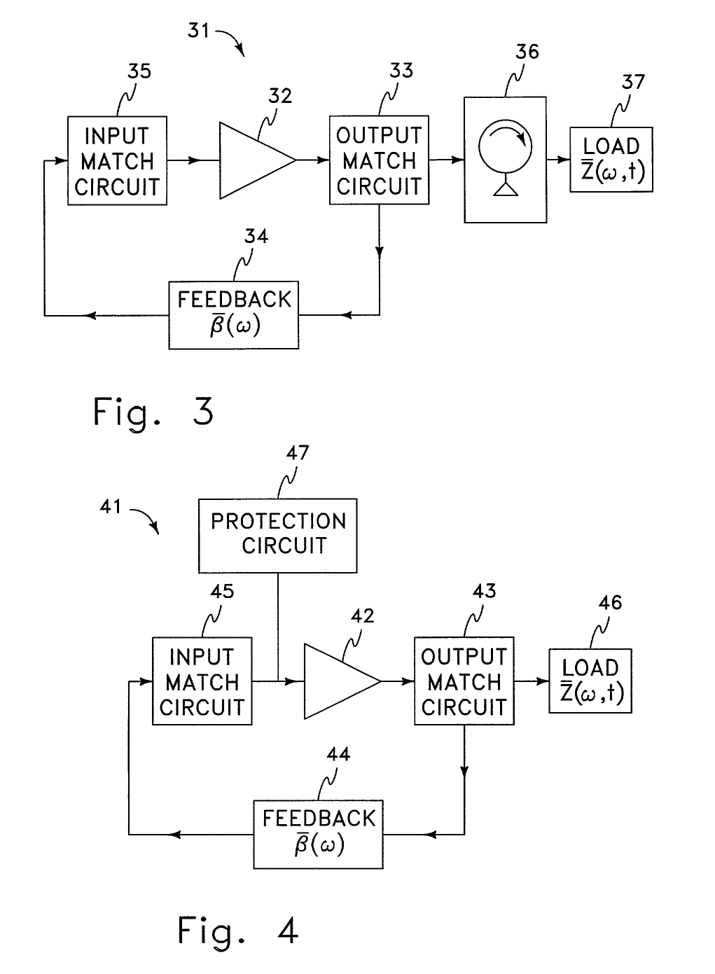

A conventional oscillator system 31 is illustrated in connection with FIG. 3. An active device 32 provides an output to an output match circuit 33. A feedback circuit 34 provides a feedback signal to an input match circuit 35 connected to an input of the active device 32. The output signal is passed through an isolator or circulator 36 to a load 37. The isolator 37 protects the oscillator circuit from high reflections by redirecting such reflections to a dummy load. The isolator 37 passes output power through itself and absorbs part of that power, thereby decreasing system efficiency. Also, isolators typically operate in a narrow frequency band, are relatively large circuit components and are relatively expensive.

With reference to FIG. 4, an oscillator system 41 according to a present aspect of the invention includes an active device 42 which provides an output to an output match circuit 43, a feedback circuit 44 connected between the output match circuit 43 and an input match circuit 45, where the feedback circuit 44 provides a feedback signal from the output of the active device to an input of the active device 42. The output signal is connected directly to a load 46. In accordance with a present aspect of the invention, the oscillator further includes a protection circuit 47 connected to an input of the active device 42 and configured to protect the active device 42 from destructive feedback.

For a power MOSFET transistor, for example, the protection circuit provides protection of the solid state power transistors from an out of range condition (e.g. an over-voltage condition) which may occur when the oscillator is operated with a dynamic high reflecting load. When the power oscillator operates with a dynamic load there are time periods when the load produces a high reflection signal. Without sufficient protection, that high reflection may produce an over-voltage condition on the gate which causes the destruction of the transistor. The gate of the transistor may be the most sensitive element of the oscillator which breakdowns by high reflection. In particular, the protection circuits described herein may be useful for protecting the power oscillators described in PCT Publication Nos. WO 99/36940 and WO 01/03161.

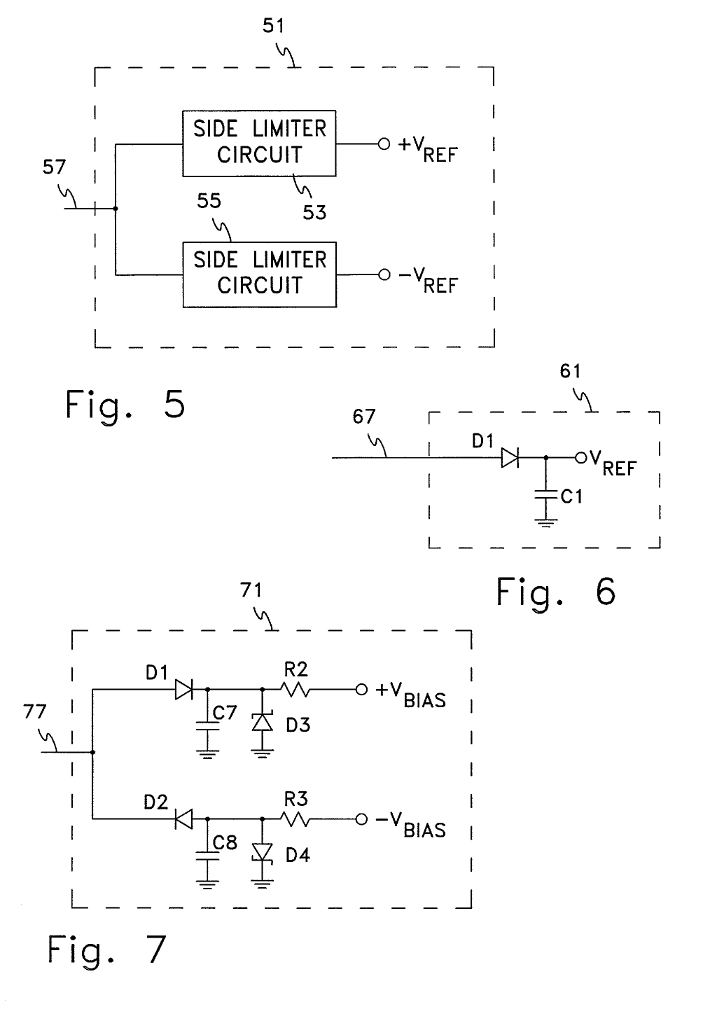

With reference to FIG. 5, a protection circuit 51 includes a pair of side limiter circuits 53 and 55. One side limiter circuit 53 is connected to a positive reference voltage +Vref and the other side limiter circuit 55 is connected to a negative reference voltage −Vref. A signal line 57 having a signal to be limited is connected to each of the pair of side limiter circuits 53 and 55. For example, the signal line 57 is connected to the input of an active device to inhibit the voltage applied to the active device from going outside of limits set in accordance with the positive and negative reference voltages. The voltage limit points are further based on a desired design margin (with respect to the active device limits) and a bias voltage applied to the active device.

Schottky diodes are often used in voltage limiting circuits. In the conventional integrated protection circuit mentioned above, a transistor with a Schottky diode connected between the gate and the source takes any large going negative cycle and shorts it to ground. Only the positive cycle turns the transistor on. One problem with this configuration is that the high current Schottky diode adds significant capacitance to the line which can adversely affect high frequency operation. The negative cycle input signal drives current through the Schottky diode and creates an additional positive bias of the transistor gate. The additional bias changes the operating range of the transistor, especially for class AB type operation. This conventional diode protection configuration is generally effective for class A linear amplification, where relatively inefficient operation is acceptable. For high frequency operation, however, a high power Schottky diode has a high capacitance at high current, which negatively impacts the operation of the active device by changing the capacitance on the input. For example, the change in capacitance may change the working point of the active device, thereby making it more difficult to maintain efficient operation of the circuit. In an oscillator configuration, the change in capacitance may change the operating frequency of the oscillator, making it more difficult to maintain a match with the load.

The present invention utilizes a combination of a PIN diode, a capacitor, and a reference voltage to overcome the above problem. Advantageously, the voltage clamping circuit of the present invention provides effective clamping at very high frequencies and high power levels without significant adverse influence on the operation of the active device.

With reference to FIG. 6, a voltage clamping circuit 61 includes a high power PIN diode D1 connected at one end to a signal line 67. The signal on the signal line 67 is an RF signal having a frequency of 300 MHz or more and a power level of 50 watts or more. A capacitor C1 is connected between the other end of the PIN diode D1 and ground. A reference voltage Vref is connected at the junction of the PIN diode D1 and the capacitor C1. The value of the capacitor C1 is selected such that the capacitor C1 effectively provides an RF short at the frequency range of interest. For example, for a power oscillator the value of C1 is selected to present a low impedance at the fundamental frequency such that when C1 is present in the circuit the RF signal is shunted to ground. In FIG. 6, the PIN diode D1 is configured with its anode connected to the signal line 67 and its cathode connected to the reference voltage Vref. In this configuration Vref sets an upper voltage limit (which may be positive or negative). To set a lower voltage limit (which may be positive or negative), the orientation of the PIN diode D1 is reversed such that its cathode is connected to the signal line 67 and its anode is connected to the reference voltage Vref. In operation, until the voltage on the signal line 67 exceeds the voltage limit (the reference voltage Vref plus the forward bias voltage of the PIN diode D1), the PIN diode D1 does not conduct and the signal 67 is substantially unaffected. When the voltage on the signal line 67 exceeds the voltage limit, the PIN diode D1 conducts and the capacitor C1 shunts the out of range voltage signal and inhibits the voltage on the signal line 67 from going beyond the voltage limit.

Another preferred schematic diagram of a protection circuit 71 is shown in FIG. 7. The protection circuit 71 includes two high power P-I-N diodes D1 and D2, two capacitors C7 and C8, two Zener diodes D3 and D4, and biasing components (e.g. resistors R2 and R3). A suitable first bias voltage +Vbias is connected to one end of a resistor R2. The other end of R2 is connected to a cathode end of a PIN diode D1, a cathode end of a Zener diode D3, and one terminal of a capacitor C7. The other end of the capacitor C7 and the anode of the Zener diode D3 are each connected to ground. A suitable second bias voltage −Vbias is connected to one end of a resistor R3. The other end of R3 is connected to an anode end of a PIN diode D2, an anode end of a Zener diode D4, and one terminal of a capacitor C8. The other end of the capacitor C8 and the cathode of the Zener diode D4 are each connected to ground. The anode end of the PIN diode D1 is connected to the cathode end of the PIN diode D2. The junction of the anode end of D1 and the cathode end of D2 is connected to a signal line 77. For example, in an oscillator circuit the junction of the PIN diodes D1 and D2 is connected to the input of the active device.

Referring back to FIG. 7, operation of the protection circuit 71 is as follows. A positive voltage (e.g. +Vbias) is applied to R2. The voltage is in excess of the Zener diode D3 reference voltage so the diode D3 conducts and the capacitor C7 charges. The resistor R2 has a fairly substantial resistance (e.g. R2=3.3 K ohms) such that at a few volts the current is on the order of milli-amps. The Zener diode D3 sets a positive reference voltage on one side of the PIN diode D1. Until the voltage on the signal line 77 (e.g. the gate of the transistor) exceeds the upper voltage limit set by D3 (the reference voltage of D3) plus the forward bias voltage of the PIN diode D1, the PIN diode D1 does not conduct and the signal on the signal line 77 is substantially unaffected. When the voltage on the signal line 77 exceeds the upper voltage limit, the PIN diode D1 conducts and the capacitor C7 shunts the over voltage signal and inhibits the voltage on the signal line 67 from increasing above the voltage limit. The other side operates similarly, but in reverse in accordance with the lower voltage limit set by the lower reference voltage (e.g. −Vbias and D2).

With the protection circuit of the present invention, the PIN diodes are reverse biased when the RF gate voltage does not exceed the respective voltage limits. The PIN diodes have small enough capacitance to avoid significant influence on the behavior of the active circuit (e.g. the amplifier or oscillator). However, the PIN diodes have very high conductivity (resistivity less than 1 Ohm) when the gate RF voltage exceeds the respective voltage limits. In that case, the capacitors C7 and C8, connected via the PIN diodes D1 and D2, operate to shunt the RF over-voltage and prevent a breakdown of the gate input of the transistor. The protection circuit 71 limits the gate RF voltage at the positive and negative level in accordance with the following:

V_{PRF}=V_{ZP}+V_{F}−V_{GB};

V_{NRF}=V_{ZN}+V_{F}+V_{GB};

and

V_{PRF}, V_{NRF}<|V_{GSMAX}|

where:

V_{PRF} is the positive voltage limit level for the RF gate voltage;

V_{NRF} is the negative voltage limit level for the RF gate voltage;

V_{F} corresponds to the forward voltage for the PIN diode (0.7V for Si);

V_{ZP} is the breakdown voltage for a Zener diode as a positive limiter;

V_{ZN} is the breakdown voltage for a Zener diode as a negative limiter;

V_{GB} is the transistor's DC gate bias voltage

|V_{GSMAX}| is the transistors maximum rating Gate−Source voltage.

With reference to FIG. 8, the operating characteristics are the PIN diode in the protection circuit are graphically represented with the above noted voltages. When the voltage level of the signal 81 is greater than the positive voltage limit (set in accordance with V_{GB}, V_{ZP}, and V_{F}) the PIN diode conducts. Likewise, when the voltage level of the signal 81 is less than the negative voltage limit (set in accordance with V_{GB}, V_{ZN}, and V_{F}) the PIN diode conducts.

For example, a power MOSFET transistor may have a gate bias voltage of about 4.5 V and a breakdown voltage (V_{GSMAX}) of +/−20V. If the signal exceeds 20V, the transistor may be destroyed. An example oscillator may have an RF signal configured to swing between +/−8V (relative to the gate bias voltage) to provide a desired power output. The protection circuit of the current invention uses Zener diodes to limit the voltage which can develop on the gate. One diode is rated at greater than 4.5+8V=12.5 (e.g. a 13V Zener diode) and the other diode is reverse biased and rated at greater than |4.5−8V|=3.5V (e.g. a 6V Zener diode). As a result if the oscillator signal exceeds 8V plus the forward voltage of the PIN diode, saturation of the Zener diode occurs, the PIN diode conducts and the capacitor becomes part of the circuit. The capacitor shunts the RF signal and the RF signal cannot increase further. Accordingly, the protection circuits limits the amount of voltage on the gate within a pre-determined range and thereby protects the gate.

In general, the protection circuit generally only operates for short transient conditions due to high reflections. Preferably, the PIN diode has a fast forward recovery time (e.g. 3 to 5 ns or less). Depending on the operating frequency, slower PIN diodes (e.g. 100 to 200 ns) may not shunt a potentially destructive voltage spike due to slow turn on. The overage comes from the fact that the signal has to be on for a certain amount of time before it conducts (the PIN diode clamping time scale). The faster PIN diodes develop only a small amount of excess voltage. Preferably, the selected upper and lower voltage limits accommodate some margin of excess voltage. For example, where the transistor breakdown voltage is 20V, the upper voltage limit may be selected to be 12V or 15V so that a small amount of voltage in excess of the upper voltage limit does not cause breakdown of the active device.

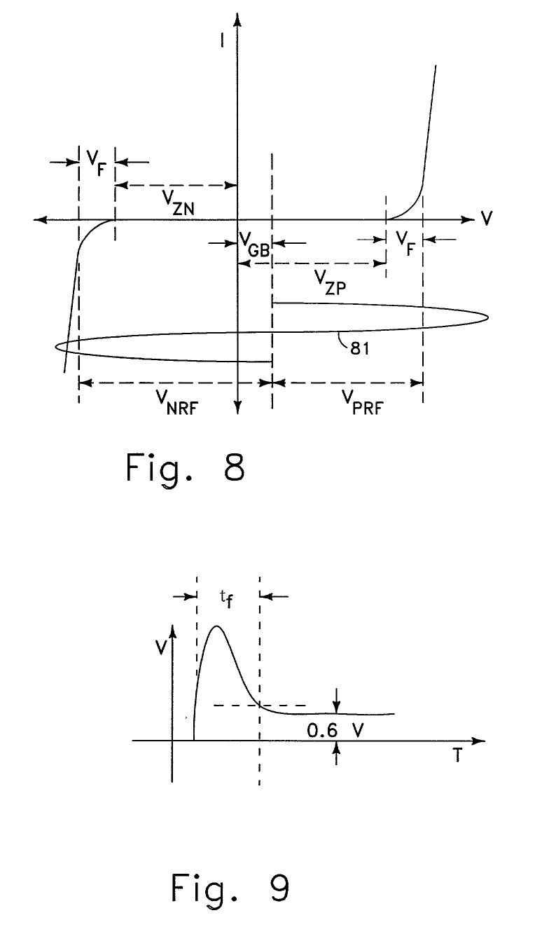

With reference to FIG. 9, a diode has a forward recovery time t_{f} corresponding to the short transient time it takes after the voltage on the PIN diode exceeds the breakdown voltage of the diode and until the diode stabilizes at 0.6V. A normal Q_{F} for good conductivity may be expressed as:

Q_{F}=I_{F}×τₚ;

and

t_{f}=Q_{F}/iₚᵢₖ

where

Q_{F} is the internal charge in the PIN diode (electrons and holes);

I_{F} is the forward current through the PIN diode;

τₚ is lifetime of the carriers of the charge in the PIN diode;

t_{f} is the forward recovery time; and

iₚᵢₖ is the driving dynamic forward current.

For a PIN diode with a transient time on the order of microseconds, the protection circuit actually start to clamp on a time scale of a few tens of nano-seconds.

For I_{F}=10 milli-amps and τₚ=2 micro-seconds (μs):

Q_{F}=10×10⁻³ amps, ×2×10⁻⁶ seconds=20×10⁻⁹ coulombs

For iₚᵢₖ=0.5 amps, t_{f}=20×10⁻⁹/0.5 amps=40 nano-seconds.

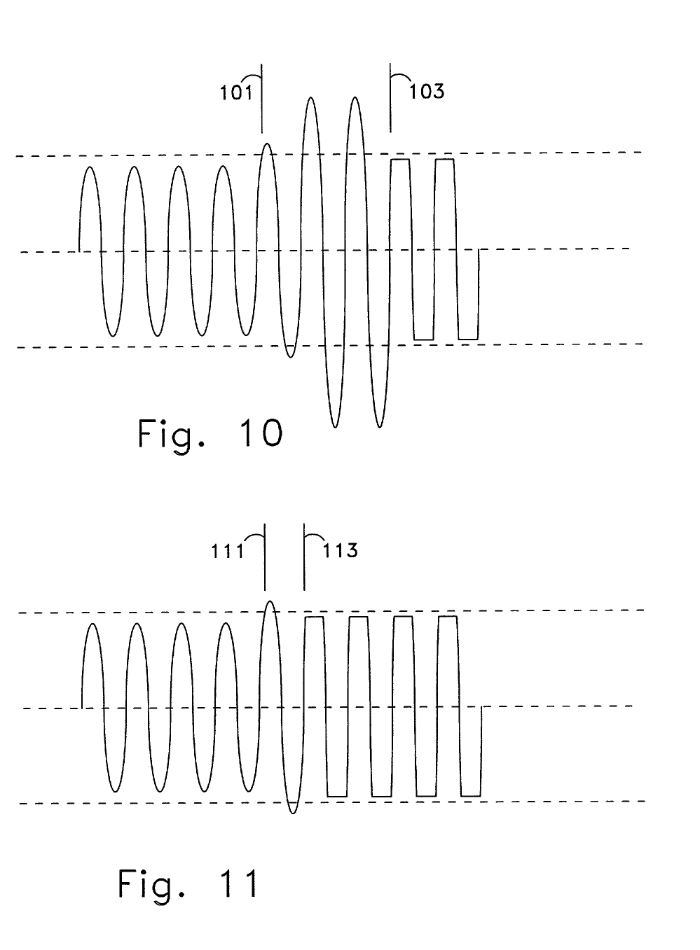

At a frequency of one gigahertz (1 GHz), the clamping may not occur for several cycles. With reference to FIG. 10, the over-voltage condition occurs at point 101 and the clamping starts at point 103, after several cycles of an excess signal. For some applications (e.g. communication), a faster PIN diode may be preferred that responds on a time scale on the order of pico-seconds, which is less than one signal cycle.

For I_{F}=10 milli-amps and τₚ=15 nano-seconds (ns):

Q_{F}=10×10⁻³ amps×15×10⁻⁹ seconds=150×10⁻¹² coulombs

For iₚᵢₖ₌0.5 amps, t_{f}=150×10⁻¹²/0.5 amps=300 pico-seconds.

With reference to FIG. 11, the over-voltage occurs at point 111 and the clamping starts at point 113, within one cycle of the over-voltage condition.

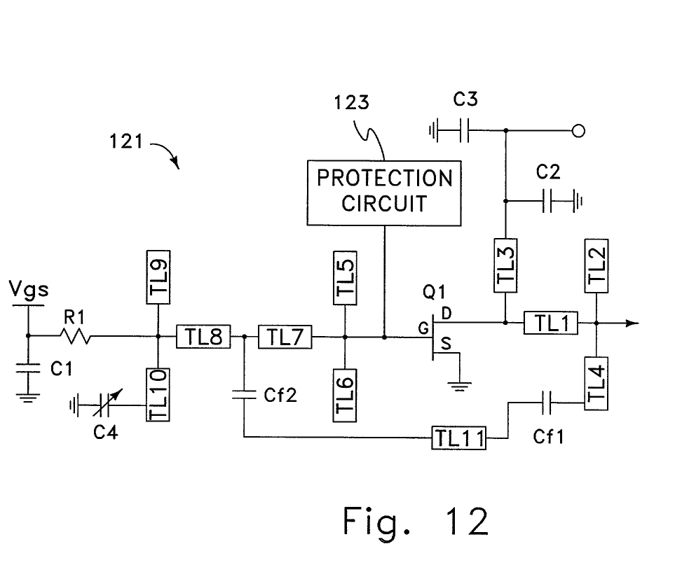

With reference to FIG. 12, an oscillator circuit 121 includes an active device Q1, such as a power LDMOS transistor. A source S of the transistor Q1 is grounded and a gate G of the transistor provides an input terminal and a drain D of the transistor provides an output terminal. A protection circuit 123 is connected to the gate of the transistor Q1.

The oscillator circuits of the present invention preferably incorporate the feedback protection principles discussed in the aforementioned '940 publication and '161 publication. Moreover, many of the oscillator circuits described in those references have stable operation without the use of isolators or circulators. However, reliability of the oscillator may be further improved by utilization of the protection circuit 123 connected to the input of the active device.

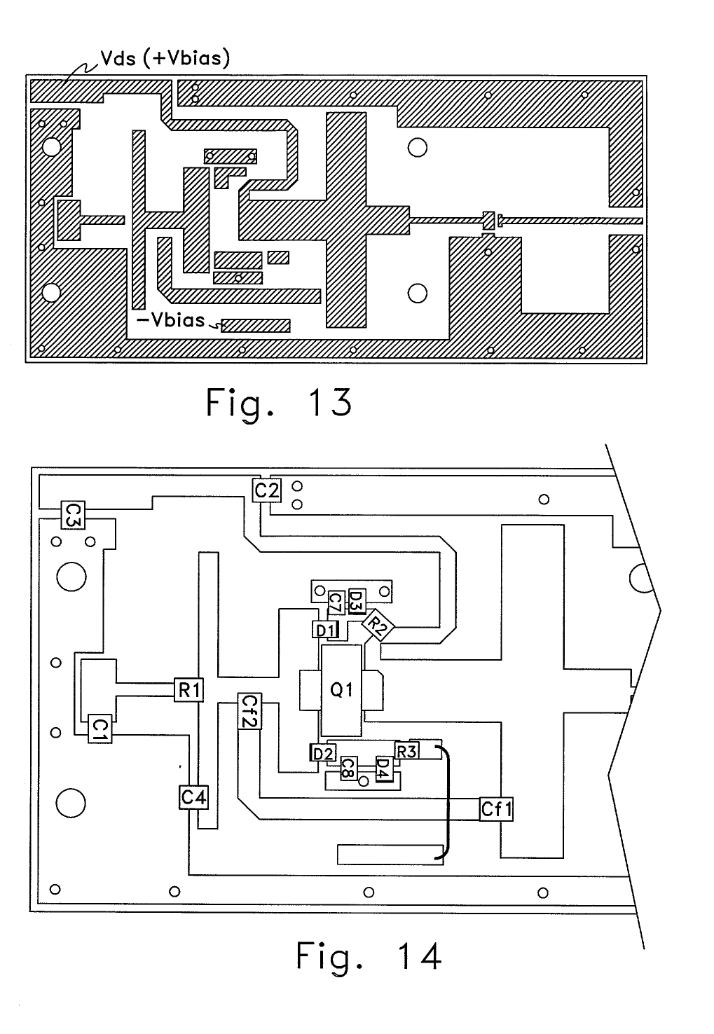

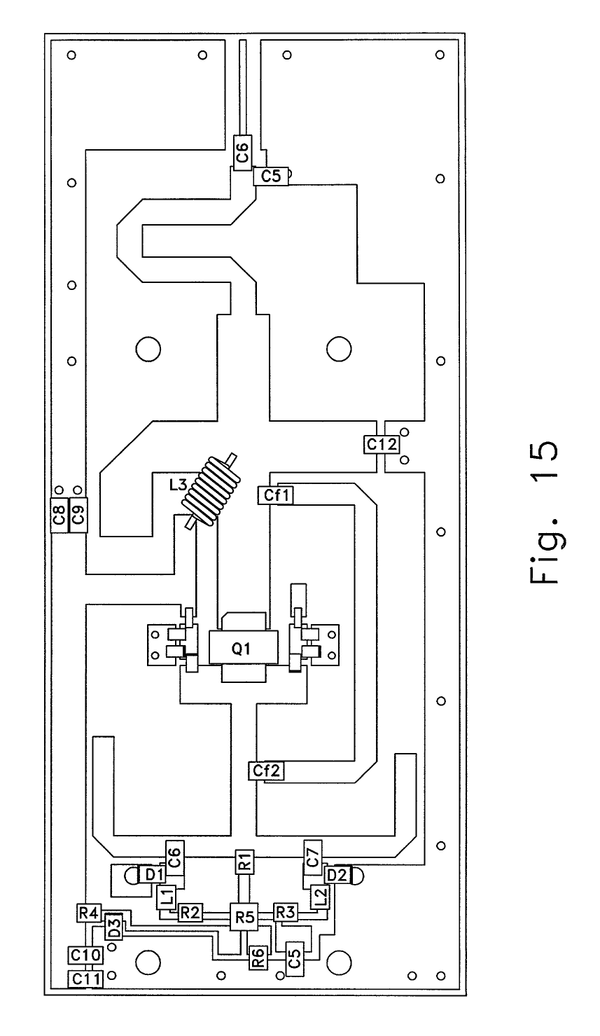

With reference to FIGS. 13-14, the DC drain voltage Vds is used as the first bias voltage +Vbias. A separate DC voltage is provided for the second bias voltage −Vbias. Suitable component values for the protection circuit are as follows:

| Reference | Description |
|---|---|
| C7 | 470 pF capacitor |
| C8 | 470 pF capacitor |
| D1 | PIN diode |
| D2 | PIN diode |
| D3 | 13 V Zener diode |
| D4 | 6 V Zener diode |
| R2 | 3.3 K ohm resistor |
| R3 | 3.3 K ohm resistor |

With reference to FIG. 15, an oscillator includes an electronically variable tuning circuit and bias circuit arrangement. Board dimensions for a fundamental frequency of approximately 430 MHz are approximately 78 mm by 176 mm and the board material has a nominal dielectric constant of 3. Suitable component values are as follows.

| Reference | Description |
|---|---|
| Q1 | RF Power FET, Spectrian URF1080 |
| Cf1 | 0.4 to 2.4 pF variable capacitor |
| Cf2 | 33 pF capacitor |
| C5 | 470 pF capacitor |
| C6 | 2.7 pF capacitor |
| C7 | 2.7 pF capacitor |
| C8 | 4700 pF capacitor |
| C9 | 1000 pF capacitor |
| C10 | 4700 pF capacitor |
| C11 | 4.7 uF capacitor |
| C12 | 9.1 pF capacitor |
| C13 | 270 pF capacitor |
| C14 | 3.9 pF capacitor |
| D1 | PIN diode |
| D2 | PIN diode |
| L1 | 330 nH inductor |
| L2 | 330 nH inductor |
| L3 | 18 AWG, 8 turn hand wound inductor |
| R1 | 100 K ohm resistor |
| R2 | 5.1 K ohm resistor |
| R3 | 5.1 K ohm resistor |
| R4 | 3.3 K ohm resistor |
| R5 | 1 K ohm variable resistor |
| R6 | 3.3 K ohm resistor |

The oscillator system shown in FIG. 15 further includes a protection circuit as described above in connection with FIG. 14, with comparable component values.

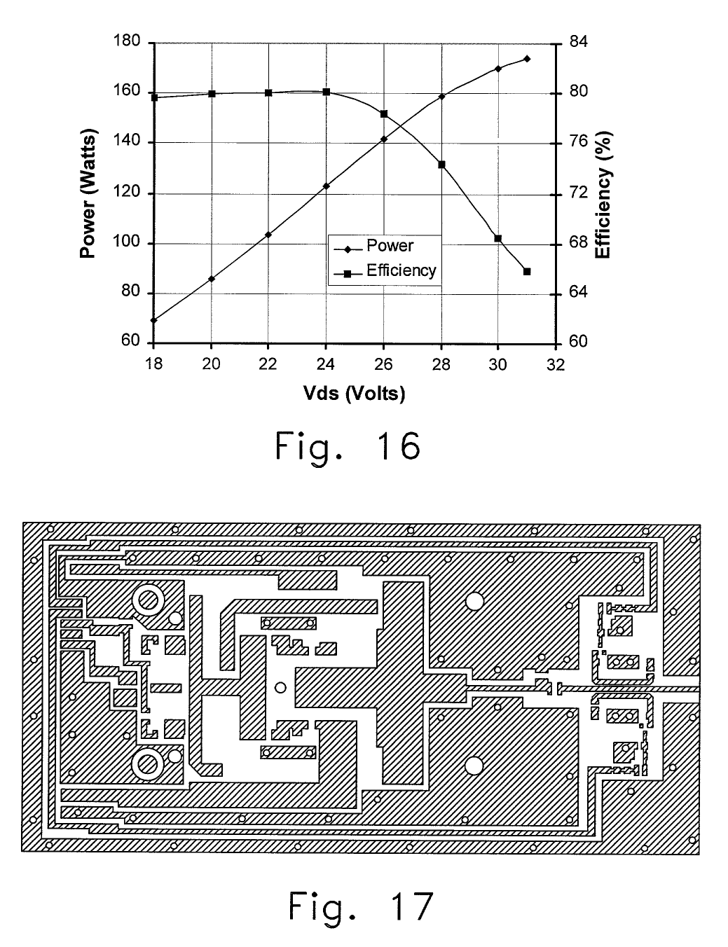

As can be seen in FIG. 16, for an operating frequency of 430 MHz the novel oscillator circuit provides efficiency of up to 80% at an output power of 125 W, without the variable tuning circuit. Power of about 160 RF Wafts is achieved at about 74% efficiency. Power in excess of 170 RF Wafts is achieved at better than 65% efficiency. The protection circuit, together with the protection provided in the feedback circuit, protects the oscillator transistor when the load impedance changes from short circuit to a nominal load (e.g. 50 Ohm) with no circulator or isolator. The protection circuit does not substantially affect the operating frequency of the oscillator or reduce the efficiency of the oscillator.

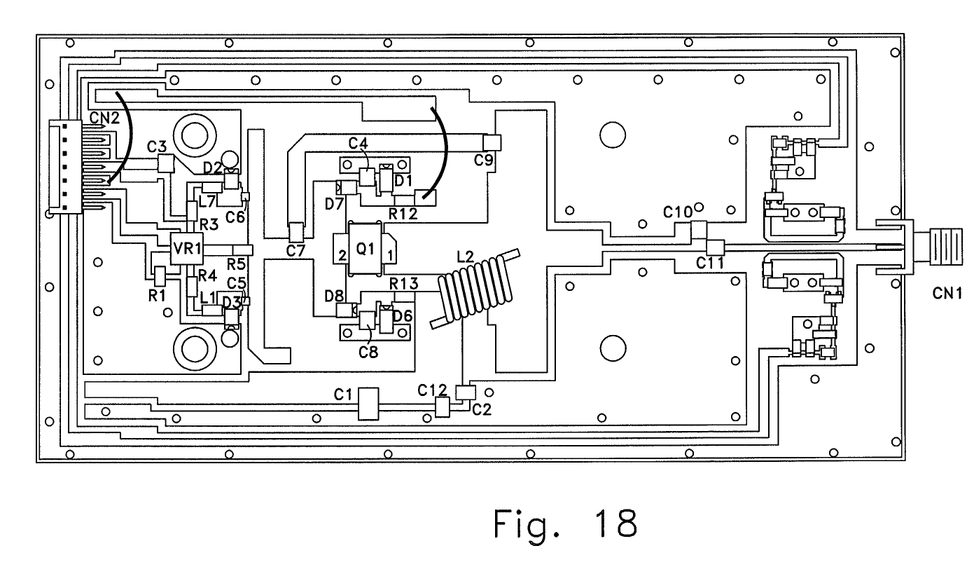

With reference to FIGS. 17-20, a power oscillator according to the present invention is configured for operation in the region of 700 MHz. The printed circuit board includes an optional integral directional coupler as described in the '161 publication for providing signals representative of forward and reflected power to an external RF control circuit. Board dimensions are approximately 80.24 mm by 164 mm and the board material has a nominal dielectric constant of 3. Suitable component values for oscillator are as follows:

| Reference | Description |
|---|---|
| Q1 | RF Power FET, Spectrian S1F90 |
| C1 | 4.7 uF capacitor |
| C2 | 4700 pF capacitor |
| C3 | 470 pF capacitor |
| C4 | 470 pF capacitor |
| C5 | 2.7 pF capacitor |
| C6 | 2.7 pF capacitor |
| C7 | 22 pF capacitor |
| C8 | 470 pF capacitor |
| C9 | 1.5 pF capacitor |
| C10 | 2 pF capacitor |
| C11 | 130 pF capacitor |
| C12 | 1000 pF capacitor |
| D1 | Zener diode, 6.2 V, 1.5 W (1SMA5920BT3) |
| D2 | PIN diode (M/A-COM MA4P7002F) |
| D3 | PIN diode (M/A-COM MA4P7002F) |
| D6 | Zener diode, 12 V, 1.5 W (1SMA5929BT3) |
| D7 | PIN diode (M/A-COM MA4P7002F) |
| D8 | PIN diode (M/A-COM MA4P7002F) |
| L1 | 330 nH inductor |
| L2 | 18 AWG, 9 turn hand wound inductor |
| L7 | 330 nH inductor |
| R1 | 3.3 K ohm resistor |
| R3 | 5.1 K ohm resistor |
| R4 | 5.1 K ohm resistor |
| R5 | 100 K ohm resistor |
| R12 | 3.3 K ohm resistor |
| R13 | 3.3 K ohm resistor |
| VR1 | 1 K ohm variable resistor (Spectrol 004G102TR) |

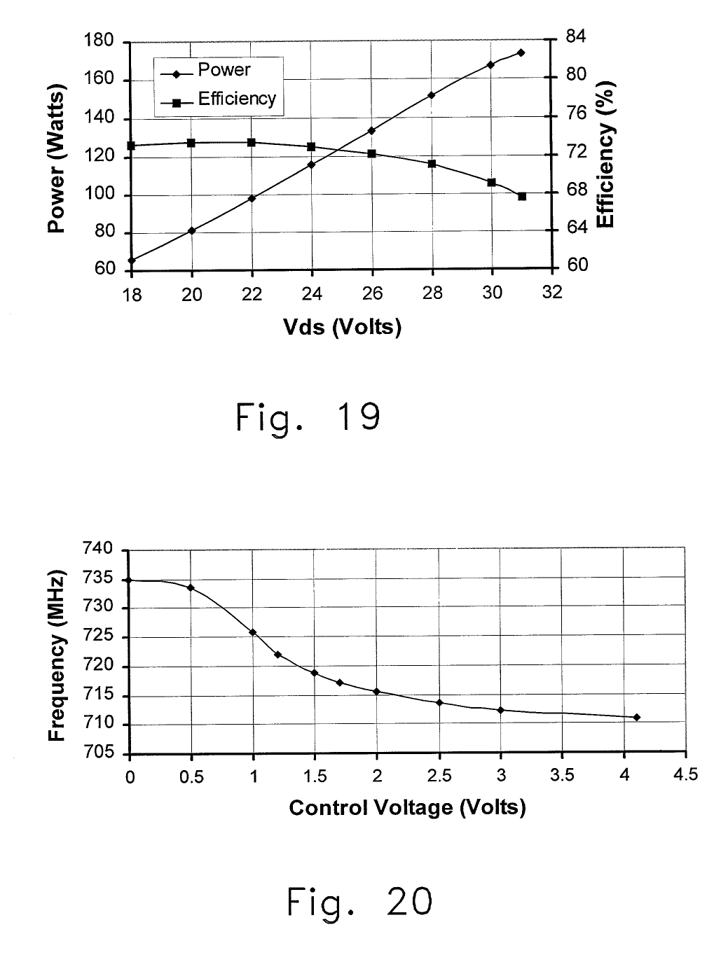

Performance data for the 700 MHz oscillator is shown in FIG. 19, without the variable tuning circuit. With the variable tuning circuit, efficiency is slightly lower. As is shown in FIG. 20, the oscillator can be tuned over a range of about 711 MHz to about 735 MHz by adjusting the control voltage on the PIN diodes D2, D3 over a range of 0 to 4.1 volts.

While the invention has been described in connection with amplifiers and oscillators using silicon transistors, the invention may be beneficially utilized with any circuit requiring voltage protection, especially at high frequencies. Other voltage sensitive devices including gallium nitride, gallium arsenide, and silicon carbide devices and other uni-polar devices would benefit from the voltage protection circuit of the present invention. Moreover, while the invention has been described in connection with what is presently considered to be the preferred examples, it is to be understood that the invention is not limited to the disclosed examples, but on the contrary, is intended to cover various modifications and equivalent arrangements included within the spirit and scope of the inventions.

What is claimed is:

1. A voltage clamping circuit, comprising:
a first side limiter circuit connected to a signal line and adapted to inhibit a voltage on the signal line from going above an upper voltage limit; and
a second side limiter circuit connected to the signal line and adapted to inhibit a voltage on the signal line from going below a lower voltage limit,
wherein a signal on the signal line has a frequency above 300 MHz and a power level above 50 watts,
and wherein each of the first and second side limiter circuits comprise a PIN diode connected to the signal line and adapted to conduct when the signal goes outside of the respective upper and lower voltage limits.

2. The voltage clamping circuit as recited in claim 1, wherein each of the PIN diodes provides a fast forward recovery time.

3. The voltage clamping circuit as recited in claim 1, wherein the frequency of the signal is greater than 400 MHz and wherein each of the PIN diodes provides a forward recovery time sufficiently fast to start clamping the signal in less than 100 nanoseconds.

4. The voltage clamping circuit as recited in claim 1, wherein the frequency of the signal is greater than 1 GHz and wherein each of the PIN diodes provides a forward recovery time sufficiently fast to start clamping the signal in less than 1 nanosecond.

5. The voltage clamping circuit as recited in claim 1, wherein each of the first and second side limiter circuits further comprises:
a Zener diode connected at a first terminal to a bias voltage selected to set the respective voltage limit and at a second terminal to ground, the first terminal of the Zener diode is also connected to a first terminal of the PIN diode;
a capacitor connected at a first terminal to the first terminal of the PIN diode and at a second terminal to ground; and
wherein the PIN diode is connected at a second terminal to the signal line.

6. A voltage clamping circuit, comprising:
a PIN diode with a first end connected to a signal line;
a capacitor connected between ground and a second end of the PIN diode; and
a reference voltage applied to the junction of the PIN diode and the capacitor.

7. The voltage clamping circuit of claim 6, further comprising a Zener diode with an anode end of the Zener diode connected to ground and wherein the reference voltage is provided by a bias voltage connected to the cathode end of the Zener diode and a cathode end of the PIN diode is connected to the cathode end of the Zener diode.

8. The voltage clamping circuit of claim 6, further comprising a Zener diode with a cathode end of the Zener diode connected to ground and wherein the reference voltage is provided by a bias voltage connected to an anode end of the Zener diode and an anode end of the PIN diode is connected to the anode end of the Zener diode.

9. The voltage clamping circuit of claim 6, wherein a signal on the signal line comprises an RF signal at a frequency of greater than 300 MHz.

10. The voltage clamping circuit of claim 6, wherein a signal on the signal line comprises an RF signal at a frequency of greater than 500 MHz.

11. The voltage clamping circuit of claim 6, wherein a signal on the signal line comprises an RF signal at a frequency of greater than 700 MHz.

12. The voltage clamping circuit of any of claims 8 to 11, wherein the signal has a power level in excess of 50 watts.

13. The voltage clamping circuit of any of claims 8 to 11, wherein the signal has a power level in excess of 100 watts.

14. A voltage clamping circuit, comprising:
a first and second PIN diode;
a first and second Zener diode; and
a first and second capacitor;
wherein an anode end of the first PIN diode and an cathode end of the second PIN diode are connected to a signal line,
the first capacitor is connected between the cathode end of the first PIN diode and ground,
a cathode end of the first Zener diode is connected to the cathode end of the first PIN diode and an anode end of the first Zener diode is connected to ground,
a first bias voltage is applied to the cathode end of the first Zener diode, and
wherein the second capacitor is connected between the anode end of the second PIN diode and ground,
an anode end of the second Zener diode is connected to the anode end of the second PIN diode and a cathode end of the second Zener diode is connected to ground, and
a second bias voltage is applied to the anode end of the second Zener diode.

15. The voltage clamping circuit of claim 14, wherein a signal on the signal line comprises an RF signal at a frequency of greater than 300 MHz.

16. The voltage clamping circuit of claim 14, wherein a signal on the signal line comprises an RF signal at a frequency of greater than 500 MHz.

17. The voltage clamping circuit of claim 14, wherein a signal on the signal line comprises an RF signal at a frequency of greater than 700 MHz.

18. The voltage clamping circuit of any of claims 15 to 17, wherein the signal has a power level in excess of 50 watts.

19. The voltage clamping circuit of any of claims 15 to 17, wherein the signal has a power level in excess of 100 watts.

20. An oscillator, comprising:
a solid state active device having an input and an output;
a feedback circuit connected from the output of the active device to the input of the active device, the feedback circuit providing suitable positive feedback to initiate and sustain an oscillating condition at a fundamental frequency; and
a voltage clamping circuit connected to the input of the active device, the voltage clamping circuit comprising:
a PIN diode connected at a first terminal to the input of the active device;
a capacitor connected between a second terminal of the PIN diode and ground; and
a reference voltage applied to a junction of the PIN diode and the capacitor.

21. The oscillator circuit of claim 20, further comprising a second voltage clamping circuit to clamp a voltage on the input of the active device within a range of upper and lower voltage limits.

22. The oscillator of claim 20, wherein the fundamental frequency of the oscillator is above 300 MHz and the output power level is above 50 watts.

23. An RF amplifier, comprising:
a solid state active device having an input and an output; and
a voltage clamping circuit connected to the input of the active device, the voltage clamping circuit comprising:
a PIN diode connected at a first terminal to the input of the active device;
a capacitor connected between a second terminal of the PIN diode and ground; and
a reference voltage applied to a junction of the PIN diode and the capacitor.

24. The RF amplifier of claim 23, further comprising a second voltage clamping circuit to clamp a voltage on the input of the active device within a range of upper and lower voltage limits.

25. The RF amplifier of claim 23, wherein a signal on the input of the active device has a frequency of above 300 MHz and the output power level is above 50 watts.
